(19) United States
(12) Patent Application Publication
(10) Pub. No.: US 2026/0293003 A1
(43) Pub. Date: Sep. 24, 2026

(54) AIR BAFFLE AND ELECTRONIC DEVICE INCLUDING AIR BAFFLE

(71) Applicant: Wistron Corporation, New Taipei City (TW)

(72) Inventors: CHU YANG KAO, New Taipei City (TW); CHEN CHOU TSAI, New Taipei City (TW); CHIA HSIN LIU, New Taipei City (TW)

(21) Appl. No.: 19/082,317

(22) Filed: Mar. 18, 2025

(30) Foreign Application Priority Data
Jan. 13, 2025 (TW) 114101318

(51) Int. Cl. H05K 5/02

(52) U.S. Cl. CPC H05K 5/0213

(57) ABSTRACT

An air baffle and an electronic device including the air baffle are disclosed. The air baffle includes: a base; a first side wall, a second side wall and a third side wall, wherein the first side wall and the second side wall are respectively connected to the third side wall, and the third side wall is connected to the base; a first vertical plate and a second vertical plate, disposed on the base and defining a holding portion collectively with the base, wherein the first vertical plate and the second vertical plate are respectively close to the first side wall and the second side wall; and a support module, disposed between the third side wall and the holding portion. The electronic device includes: a housing containing a first side plate and a second side plate disposed opposite each other; and the air baffle disposed within the housing.

### CROSS REFERENCE TO RELATED APPLICATION

This application claims the priority benefit of Taiwan Patent Application No. 114101318, filed on Jan. 13, 2025. The entirety of the mentioned above patent application is hereby incorporated by reference herein and made a part of this specification.

### BACKGROUND OF THE INVENTION

### 1. Field of the Invention

The present invention relates to an air baffle and an electronic device including an air baffle. Specifically, the present invention relates to an air baffle including a support module and an electronic device including an air baffle.

### 2. Description of the Prior Art

As the components in electronic devices become increasingly complex and refined, it becomes more challenging to configure these components in a limited space while achieving the intended functionalities. Moreover, modern electronic devices often have expandable features, requiring external hardware for additional demands such as image processing, audio processing, network processing, graphics processing and so on, thus requiring the reservation of space and the structural design for positioning these external components. Therefore, when arranging various components, one should consider not only the minimization of the space occupied but also the electrical connection requirements, heat dissipation needs, mounting requirements, protection needs, and external connection demands of each component. However, these factors for consideration often require coordination in spatial allocation and may even lead to conflicts.

In light of this, how to securely fix and protect various components or external hardware while minimizing or preventing obstruction of cooling airflow or cable routing pathways has become one of the key focuses in designing these electronic devices, especially for those components or external hardware that are larger, heavier, or more fragile, such as an expansion card (for example, but not limited to, a PCIE card), a battery, a HDD, a PSU and the like. As mentioned above, there is a need to develop a configurational design that can integrate various components while minimizing space usage and retaining the original intended functions of cable routing, securing, protection, and cooling.

### SUMMARY OF THE INVENTION

### Technical Means to Solve the Problems

To solve the above problems, according to an embodiment of the present disclosure, an air baffle is provided, wherein the air baffle includes: a base; a first side wall, a second side wall and a third side wall, wherein the first side wall and the second side wall are respectively connected to the third side wall, and the third side wall is connected to the base; a first vertical plate and a second vertical plate, disposed on the base and defining a holding portion collectively with the base, wherein the first vertical plate and the second vertical plate are respectively close to the first side wall and the second side wall; and a support module, disposed between the third side wall and the holding portion.

In another embodiment of the present disclosure, an electronic device is provided, wherein the electronic device includes: a housing containing a first side plate and a second side plate disposed opposite each other; and an air baffle disposed within the housing. The air baffle includes: a base; a first side wall, a second side wall and a third side wall, wherein the first side wall and the second side wall are respectively connected to the third side wall, and the third side wall is connected to the base; a first vertical plate and a second vertical plate, disposed on the base and defining a holding portion collectively with the base, wherein the first vertical plate and the second vertical plate are respectively close to the first side wall and the second side wall; and a support module, disposed between the third side wall and the holding portion. The first side wall and the second side wall of the air baffle respectively lap over the first side plate and the second side plate of the housing.

### Effects in Comparison to Prior Art

Based on the air baffle and the electronic device including the air baffle provided in various embodiments of the present disclosure, the air baffle used for cooling is further utilized to secure and protect a predetermined component such as an expansion card (including but not limited to a PCIE card), thereby reducing the space required for configuring the components and, at the same time, improving the robustness and protection of the predetermined component. In addition, based on the air baffle and the electronic device including the air baffle provided in various embodiments of the present disclosure, the impact on heat dissipation and/or cable arrangement can be reduced when configuring a predetermined component. Therefore, based on the air baffle and the electronic device including the air baffle provided in various embodiments of the present disclosure, the overall space arrangement can be optimized while ensuring the intended functionality of each component and enhancing the support and reliability of the entire structure.

### BRIEF DESCRIPTION OF THE DRAWINGS

FIG. 1 is an exploded view of the air baffle according to an embodiment of the present invention.

FIG. 2 is a 3D schematic diagram of the air baffle from a first viewing angle according to an embodiment of the present invention.

FIG. 3 is a 3D schematic diagram of the air baffle from a second viewing angle according to an embodiment of the present invention.

FIG. 4 is a schematic diagram of the air baffle from a third viewing angle and the corresponding sectional diagram from a fourth viewing angle according to an embodiment of the present invention.

FIG. 5 is a schematic diagram of using the air baffle to position a predetermined component according to an embodiment of the present invention.

FIGS. 6 and 7 are comparison diagrams of switching the position of the module body between different grooves according to an embodiment of the present invention.

FIG. 8 is an enlarged view of the module body clamping the expansion card according to an embodiment of the present invention.

FIG. 9 is a 3D schematic diagram of the electronic device including the air baffle according to an embodiment of the present invention.

FIG. 10 is a 3D schematic diagram of the first supporting wall and the second supporting wall of the air baffle respectively lapping over the first blocking plate and the second blocking plate of the holder according to an embodiment of the present invention.

FIG. 11 is an exploded view of the air baffle and the corresponding first blocking plate or second blocking plate of the holder according to another embodiment of the present invention.

FIG. 12 is a 3D schematic diagram of using the top cover to cover and protect the inside of the housing according to an embodiment of the present invention.

FIG. 13 is a simplified diagram of the module body of the support module in the air baffle, wherein the module body abuts the top cover, according to an embodiment of the present invention

FIG. 14 is a schematic diagram of the stress transfer path of a predetermined component such as an expansion card according to an embodiment of the present invention.

FIG. 15 is a flow chart of assembling the electronic device according to an embodiment of the present invention.

FIG. 16 is a 3D schematic diagram of assembling the air baffle into the housing according to an embodiment of the present invention.

FIG. 17 is a 3D schematic diagram of assembling a predetermined component such as an expansion card onto the air baffle according to an embodiment of the present invention.

FIG. 18 is a 3D schematic diagram of switching the position of the module body of the support module to clamp a predetermined component such as an expansion card according to an embodiment of the present invention.

### DETAILED DESCRIPTION OF THE INVENTION

Various embodiments will be described below, and a person having ordinary skill in the art can easily understand the spirits and principles of the present disclosure by referring to this specification accompanied by the drawings. However, although some particular embodiments will be specifically illustrated herein, these embodiments are only exemplary, and are not regarded as limiting or exhaustive in all respects. Therefore, for a person having ordinary skill in the art, various changes and modifications to the present disclosure should be obvious and can be easily achieved without departing from the spirits and principles of the present disclosure.

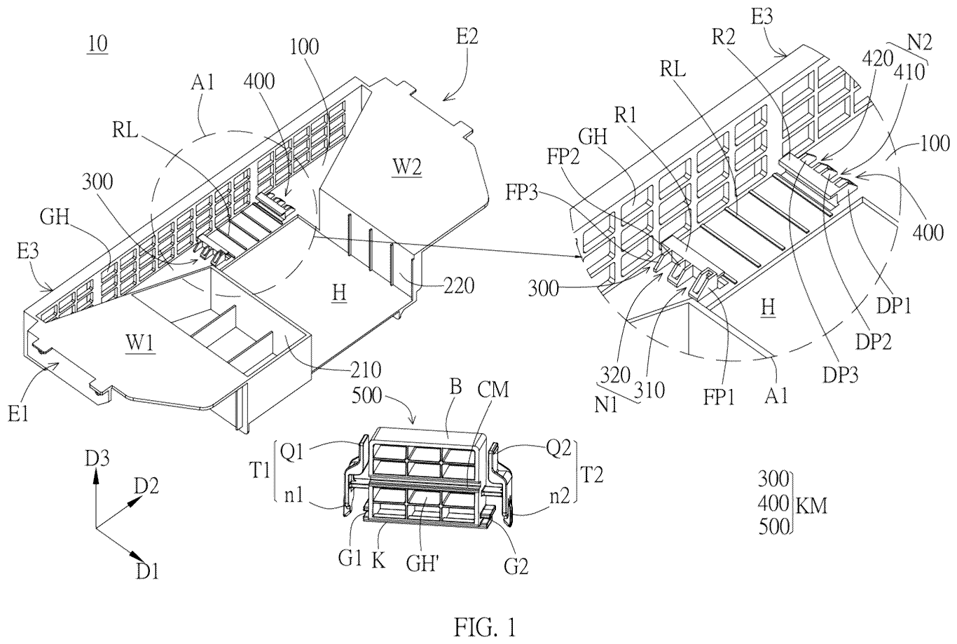

Referring to FIGS. 1 to 3, an air baffle 10 is provided in an embodiment of the present disclosure, wherein the air baffle 10 includes: a base 100, a first side wall E1, a second side wall E2, a third side wall E3, a first vertical plate 210, a second vertical plate 220, and a support module KM. Wherein the first side wall E1 and the second side wall E2 are respectively connected to the third side wall E3, and the third side wall E3 is connected to the base 100. In addition, the first vertical plate 210 and the second vertical plate 220 may be disposed on the base 100 and between the first side wall E1 and the second side wall E2, and the first vertical plate 210 and the second vertical plate 220 may be respectively close to the first side wall E1 and the second side wall E2. Therefore, the first vertical plate 210 and the second vertical plate 220 can define a holding portion H collectively with the base 100.

In the above embodiment, the air baffle 10 may further include a first supporting wing W1 and a second supporting wing W2. The first supporting wing W1 may be connected to the first side wall E1 and the first vertical plate 210 and disposed therebetween. The second supporting wing W2 may be connected to the second side wall E2 and the second vertical plate 220 and disposed therebetween. Based on this structure, the first side wall E1, the second side wall E2, the first supporting wing W1 and/or the second supporting wing W2 may be suitable for configuring and securing the air baffle 10 onto a predetermined object or a predetermined pedestal, as well as for further supporting the holding portion H defined by the first vertical plate 210 and the second vertical plate 220.

In the embodiment shown in FIGS. 1 to 3, the support module KM may be disposed between the third side wall E3 and the holding portion H. Specifically, the support module KM may include a first positioning portion 300, a second positioning portion 400, and a module body 500. The first positioning portion 300 and the second positioning portion 400 may be disposed on the base 100 and respectively close to the first vertical plate 210 and second vertical plate 220. In addition, the module body 500 may be connected with the first positioning portion 300 and the second positioning portion 400 and used to move toward or away from the holding portion H.

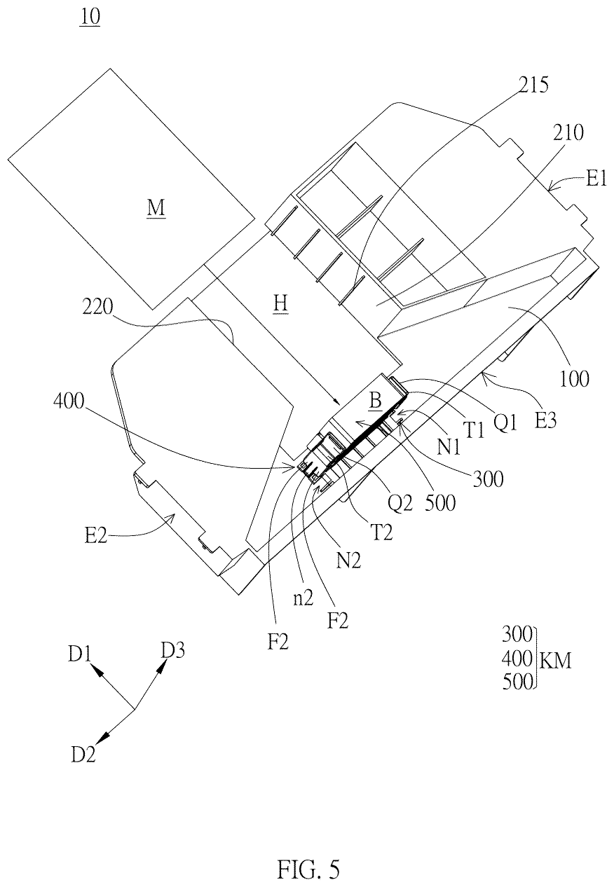

To be more specific, referring to FIGS. 1 to 3, particularly the enlarged view of the region A1 in FIG. 1, the first positioning portion 300 and the second positioning portion 400 may be disposed on one side of the holding portion H. According to this embodiment, the first positioning portion 300 may have a first guide rail R1 extending toward the second positioning portion 400, and the second positioning portion 400 may have a second guide rail R2 extending toward the first positioning portion 300. Correspondingly, the two sides of the module body 500 may have a first slide rail G1 and a second slide rail G2. Based on this configuration, when the module body 500 is disposed on the base 100, the first slide rail G1 and the second slide rail G2 of the module body 500 may respectively fit with the first guide rail R1 of the first positioning portion 300 and the second guide rail R2 of the second positioning portion 400, allowing the module body 500 to be slidably positioned on the base 100. In addition, as shown in FIGS. 1 to 3, the support module KM may include a clamping slot CM disposed on the middle part of the module body 500, wherein the opening of the clamping slot CM is oriented toward the holding portion H, thus allowing the clamping slot CM to be used for clamping and positioning the predetermined component M (referring to FIG. 5). In addition, according to some embodiments, the module body 500 may have a bottom edge K close to the base 100, and the predetermined component M may also be abutted by the bottom edge K of the module body 500 to be positioned between the module body 500 and the base 100. Therefore, based on this configuration, the module body 500 can move in a sliding manner to achieve and adjust the clamping and positioning of the predetermined component M.

Specifically, based on this embodiment, the first positioning portion 300 of the support module KM may have at least one first groove N1 opening away from the base 100, and the second positioning portion 400 may have at least one second groove N2 opening away from the base 100. In addition, two sides of the module body 500 may respectively have a first arm T1 and a second arm T2. The first arm T1 and the second arm T2 may respectively extend to one of the first groove(s) N1 and one of the second groove(s) N2 to position the module body 500. The first arm T1 may have a first insert end n1 close to the bottom edge K and a first pressing end Q1 away from the bottom edge K, and the second arm T2 may have a second insert end n2 close to the bottom edge K and a second pressing end Q2 away from the bottom edge K. Thus, when the module body 500 is in the locked state, the first insert end n1 may be fastened into one of the first groove(s) N1, and the second insert end n2 may be fastened into one of the second groove(s) N2. In addition, in order to release the module body 500 from the locked state, the user can press the first pressing end Q1 of the first arm T1 and the second pressing end Q2 of the second arm T2 to remove the first insert end n1 and the second insert end n2 respectively from the corresponding first groove N1 and the second groove N2, allowing the module body 500 to move along the extending direction (i.e., the first direction D1, for example, the horizontal direction) of the first guide rail R1 and the second guide rail R2. As mentioned above, the user can release the module body 500 of the support module KM from the locked state to move the module body 500. Therefore, the module body 500 of the support module KM can slide and be fastened into the locked state and then clamped to the predetermined component M (referring to FIG. 5). Here, we only focus on the structural configuration of the components in this process, and the above process will be further elaborated with reference to other figures in the following context.

For example, referring to FIG. 1, according to some embodiments of the present disclosure, the first positioning portion 300 may, for example, have a plurality of first bumps FP1, FP2, and FP3 arranged with spacing, and the second positioning portion 400 may, for example, have a plurality of second bumps DP1, DP2, and DP3 arranged with spacing. Based on this configuration, the position of the module body 500 can be limited by the first bumps FP1, FP2, and FP3 and the second bumps DP1, DP2, and DP3 on both sides of the module body 500, thereby preventing movement in an unintended direction such as a second direction D2. Furthermore, the first grooves N1 may be defined between the first bumps FP1, FP2, and FP3 arranged with spacing. For example, the first groove 310, being close to the holding portion H, may be defined between the first bump FP1 and the first bump FP2, and another first groove 320, being away from the holding portion H, may be defined between the first bump FP2 and the first bump FP3. Similarly, the second grooves N2 may be defined between the second bumps DP1, DP2, and DP3. For example, the second groove 410, being close to the holding portion H, may be defined between the second bump DP1 and the second bump DP2, and the second groove 420, being away from the holding portion H, may be defined between the second bump DP2 and the second bump DP3.

In addition, according to this embodiment, the first guide rail R1 may be positioned at a distance from the base 100 and extend from the first bumps FP1, FP2, and FP3 to the second positioning portion 400 along the second direction D2 (for example, the horizontal direction), wherein the first bumps FP1, FP2, and FP3 and the first guide rail R1 may be formed as a single piece. Similarly, the second guide rail R2 may be positioned at a distance from the base 100 and extend from the second bumps DP1, DP2, and DP3 to the first positioning portion 300 along the second direction D2 (for example, the horizontal direction), wherein the second bumps DP1, DP2, and DP3 and the second guide rail R2 may be formed as a single piece. However, the above configurations are only exemplary, while other configurations can also be adopted according to other embodiments of the present invention. For example, each of the first bumps FP1, FP2, the FP3 may have a first guide rail R1 extending toward the second positioning portion 400, and these first guide rails R1 are not connected but are arranged in segments on the same horizontal plane to facilitate sliding; similarly, each of the second bumps DP1, DP2, and DP3 may have a second guide rail R2 extending toward the first positioning portion 300, and these second guide rails R2 are not connected but are arranged in segments on the same horizontal plane to facilitate sliding.

In addition, although it is specifically shown here that the grooves and guide rails are defined by the bumps, they are not limited thereto according to other embodiments of the present invention. For example, according to some embodiments, the grooves may be created by forming recesses in a strip structure, and the first guide rail R1 and the second guide rail R2 may be formed apart from the strip structure to insert into the first slide rail G1 and the second slide rail G2. As mentioned above, according to other embodiments of the present invention, the first positioning portion 300 and the second positioning portion 400 can have various variations without departing from the spirit of the present invention. Furthermore, according to some embodiments, in order to improve the smoothness of the sliding of the module body 500, a guiding rail RL or other assisting structures may be disposed on the base 100 between the first positioning portion 300 and the second positioning portion 400 and extend along an intended sliding direction such as the first direction D1, but not limited thereto.

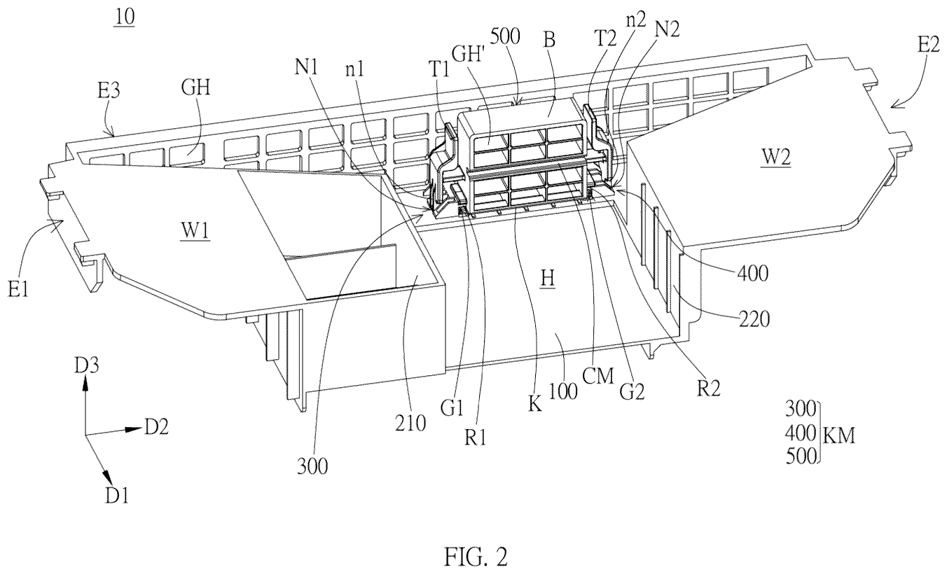

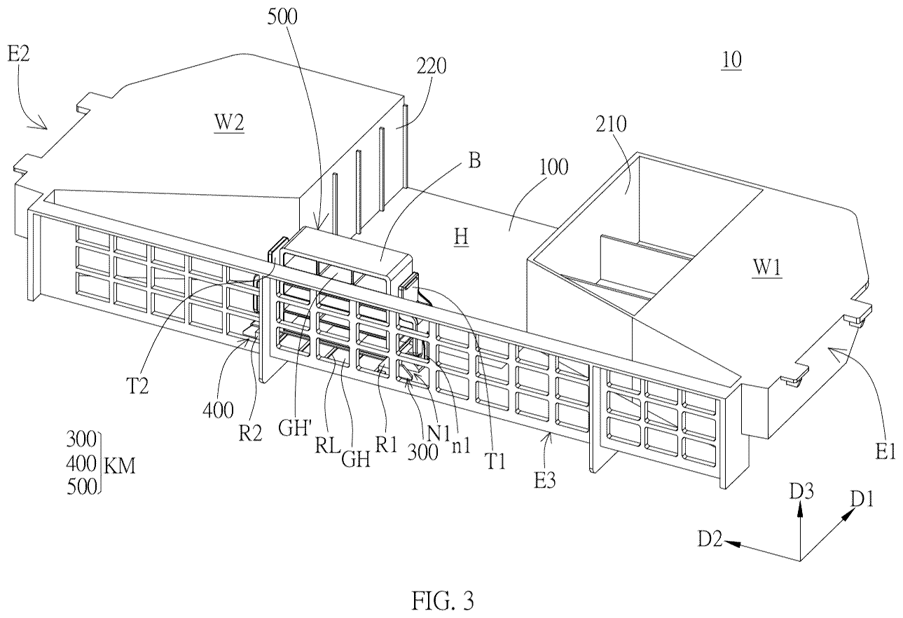

Referring to the schematic diagrams of the module body 500 positioned between the first positioning portion 300 and the second positioning portion 400 shown in FIG. 2 and FIG. 3, as well as the exploded view in FIG. 1, according to this embodiment, the module body 500 may be disposed on the base 100 and the position of the module body 500 may be limited by the first positioning portion 300 and the second positioning portion 400, wherein the module body 500 is slidable along the first direction D1 and can be positioned in different sites. Therefore, when the predetermined component M is positioned into the holding portion H, the user can switch the position of the module body 500 along the first direction D1 to clamp and secure an end of the predetermined component M by the clamping slot CM of the module body 500 or the bottom edge K of the module body 500; or, both the clamping slot CM and the bottom edge K can be used at the same time to secure one or more predetermined components M. Thus, based on the air baffle 10 in this embodiment, the functions of securing the predetermined component M can be further integrated with the intended flow-guided cooling function.

According to some embodiments, as shown in FIGS. 1 to 3. the air baffle 10 itself may have a plurality of flow-guiding via holes GH based on the intended design to achieve cooling through airflow guiding. The flow-guiding via holes GH is positioned on the third side wall E3 of the air baffle 10. Therefore, the flow-guiding via hole GH is on the sides of the first positioning portion 300 and the second positioning portion 400 away from the holding portion H. Furthermore, according to this embodiment, the module body 500 of the support module KM may have a plurality of air channels GH′, wherein the air channels GH′ can be connected to the flow-guiding via holes GH. Therefore, air can flow through the holding portion H into the air channels GH′, then pass through the flow-guiding via holes GH, directing toward the external space. As mentioned above, according to this embodiment, even though the support module KM is used to enhance the support to and protection of the predetermined component M (referring to FIG. 5), the airflow can still flow smoothly, thereby reducing or preventing impacts on the cooling effect.

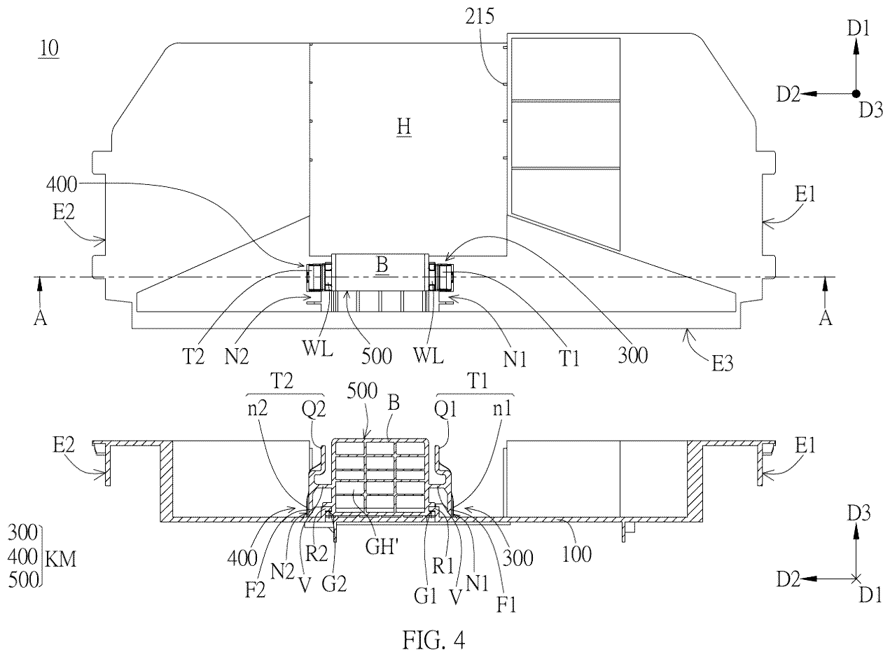

Next, referring to FIG. 4, which shows a top view of the air baffle 10 as well as a sectional view taken along the profile line A-A′, one can clearly see the detailed configuration relationship between the module body 500, the first positioning portion 300, and the second positioning portion 400 in the assembled scenario according to an embodiment of the present invention. Specifically, as shown in FIG. 4, the first arm T1 of the module body 500 may be connected to one side of the body B of the module body 500 via the pivot component V. Therefore, the first arm T1 can be operated in a lever-like motion based on the pivot component V. When the user presses the first pressing end Q1 close to the body B of the module body 500, the first insert end n1 can be relatively lifted up away from the body B of the module body 500 and be removed from one of the first grooves N1. In addition, referring to FIG. 4, the second arm T2 of the support module KM may have a similar configuration and can be operated in a manner similar to the first arm T1. Therefore, the user can unlock the module body 500 by pressing the first pressing end Q1 and the second pressing end Q2 of the module body 500 at the same time, allowing the module body 500 to move freely along the horizontal direction such as the first direction D1.

As mentioned above, according to this embodiment, the first arm T1 and the second arm T2 can respectively be operated in a lever-like motion using the pivot component V. The module body 500 has a first slide rail G1 and a second slide rail G2, wherein the first slide rail G1 and the second slide rail G2 may respectively extend along the second direction D2 away from the body B of the module body 500. Therefore, the first guide rail R1 extending from the first positioning portion 300 can be inserted into the first slide rail G1, and the second guide rail R2 extending from the second positioning portion 400 can be inserted into the second slide rail G2, thereby allowing the module body 500 to slide along the first guide rail R1 and the second guide rail R2 when the module body 500 is unlocked.

Furthermore, according to some embodiments of the present disclosure and referring to FIGS. 4 and 5, the first insert end n1 may further have one or more reinforcing end pieces F1, and the second insert end n2 may further has one or more reinforcing end pieces F2. The reinforcing end piece(s) F1 and the reinforcing end piece(s) F2 may be positioned on the lateral sides of the first insert end n1 and the second insert end n2 to provide position-limiting functions and protection, thereby preventing the portions of the first insert end n1 and the second insert end n2 that are intended to be respectively inserted into the first groove N1 and the second groove N2 from unintended bending as well as unintended misalignment or displacement from the first groove N1 and the second groove N2.

Referring to FIGS. 4 and 5, the air baffle 10 of this embodiment may be used to support and position a predetermined component M. According to some embodiments, the first vertical plate 210 and the second vertical plate 220 on both sides of the holding portion H can be used to clamp the predetermined component M in a predetermined direction such as the second direction D2 to block the displacement of predetermined component M. According to some embodiments, in order to enhance stability and prevent slipping, the first vertical plate 210 and the second vertical plate 220 may respectively have rib parts 215, but not limited thereto. As mentioned above, by switching the position of the module body 500 in the air baffle 10 of this embodiment, clamping and securing an end of the predetermined component M can be further achieved using the module body 500.

Continuing referring to FIGS. 4 and 5, since the module body 500 itself is not movable along the vertical direction such as the third direction D3, positioning and protection of the predetermined component M can be further enhanced based on this configuration, reducing or preventing wobbling during operation or transportation, or at least conducting and/or absorbing the stress from the aforementioned shaking. Furthermore, in the predetermined direction such as the first direction D1, when the module body 500 is in the locked state, the elasticity of the first arm T1 and the second arm T2 allow the first insert end n1 and the second insert end n2 to be securely fastened into one of the first grooves N1 and one of the second grooves N2, respectively. In addition, according to this embodiment, the width of the first insert end n1 in the predetermined direction such as the first direction D1 can fit with the width of each first groove N1 in the predetermined direction such as the first direction D1, and the width of the second insert end n2 in the predetermined direction such as the first direction D1 can fit with the width of each second groove N2 in the predetermined direction such as the first direction D1. Therefore, when the module body 500 is fastened into one of the first grooves N1 and one of the second grooves N2, the module body 500 can be securely positioned in the predetermined direction such as first direction D1 without wobbling or moving along the predetermined direction such as the first direction D1. As mentioned above, according to this embodiment, the positioning and protection of the predetermined component M can be further ensured.

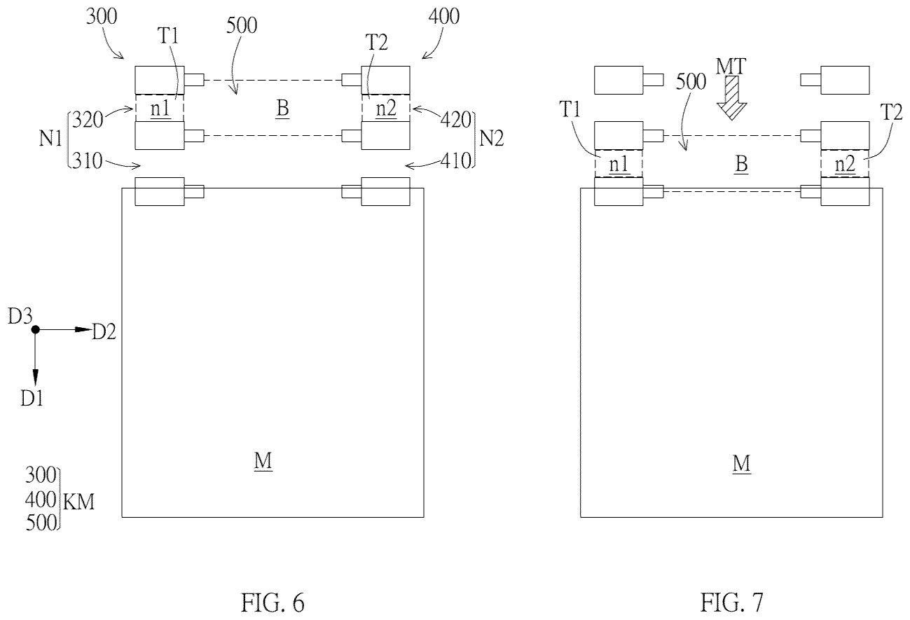

In addition, when the first pressing end Q1 and the second pressing end Q2 on both sides of the module body 500 are pressed, the first slide rail G1 and the second slide rail G2 can respectively slide along the first guide rail R1 and the second guide rail R2 in the horizontal direction such as the first direction D1, thereby allowing the module body 500 to have a translational degree of freedom in the horizontal direction such as the first direction D1. Therefore, based on the detailed configuration of this embodiment, the module body 500 may selectively move along the predetermined direction such as the first direction D1 to the different grooves for further positioning. For example, referring to FIGS. 4 and 5 as well as the simplified diagram shown in FIGS. 6 and 7, when a predetermined component M such as an expansion card is not inserted into the holding portion H, the module body 500 may be positioned away from the holding portion H, wherein the first insert end n1 and the second insert end n2 is respectively positioned in one of the first grooves N1 (such as the first groove 320) and one of the second grooves N2 (such as the second groove 420) away from the holding portion H. The user can operate the module body 500 using the first slide rail G1 and the second slide rail G2 to slide a sliding distance MT along the first direction D1 relative to the first guide rail R1 and the second guide rail R2, approaching the predetermined component M. Then, the first insert end n1 and the second insert end n2 are respectively fastened into the other first groove N1 (such as the first groove 310) and the other second groove N2 (such as the second groove 410) close to the holding portion H. In the meantime, the module body 500 can be used to clamp the predetermined component M in the locked state.

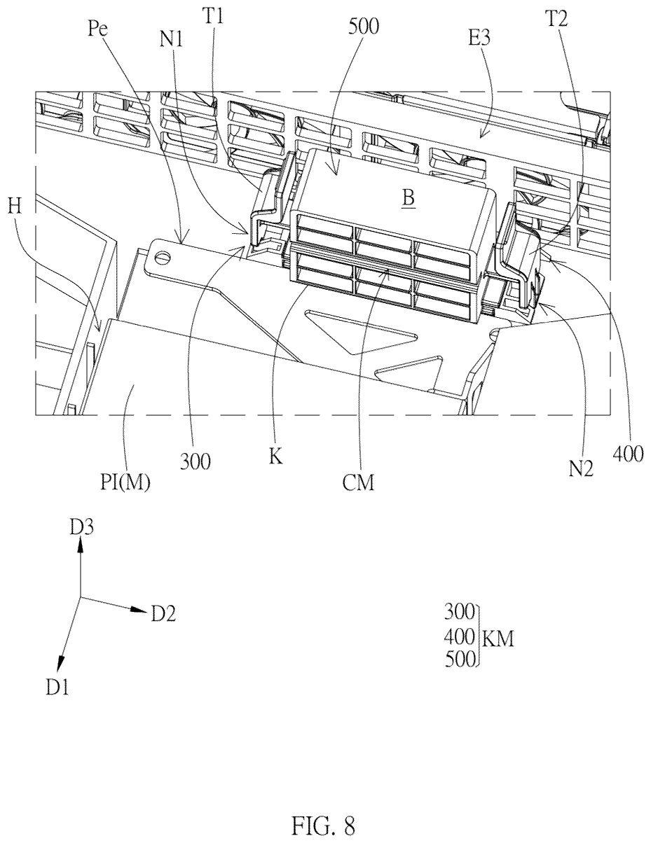

For example, referring to FIG. 8, by the above configuration and operation, according to an embodiment of the present disclosure, the module body 500 can be used to clamp an end of the predetermined component M, for example, the end Pe of the expansion card PI, by using the clamping slot CM or the bottom edge K. However, the above is merely exemplary, and based on different embodiments of the present invention, the object for the module body 500 of the support module KM to clamp/hold is not limited thereto.

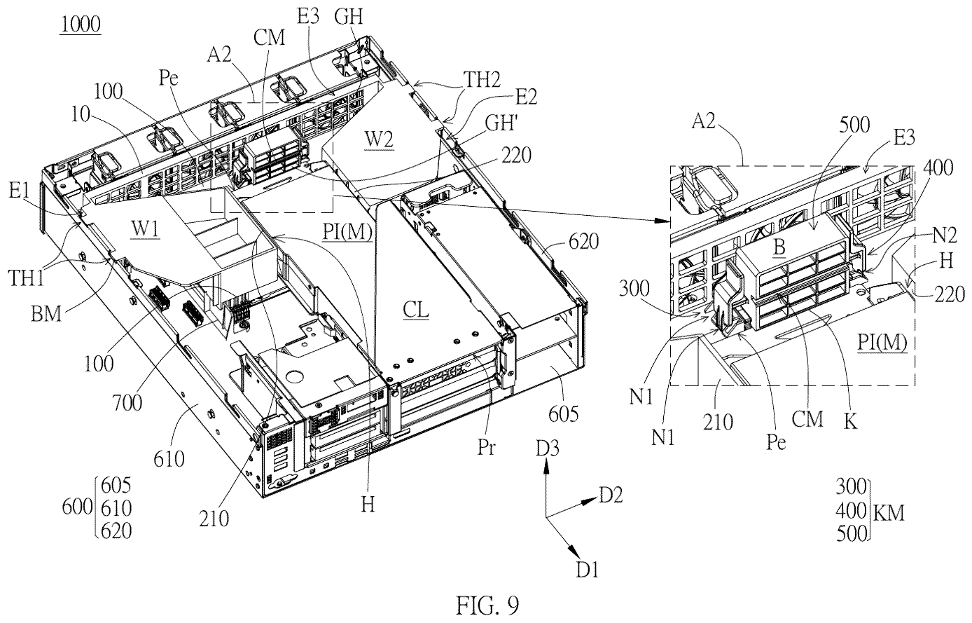

Next, according to an embodiment of the present invention, the electronic device 1000 including the aforementioned air baffle 10 will be illustrated based on FIGS. 9 to 13. Details that are the same as or similar to those previously described with reference to FIGS. 1 to 8 may be omitted, and the focus will be mainly on further technical details that have not been discussed above.

As shown in FIG. 9, according to an embodiment of the present disclosure, the air baffle 10 can be configured within the electronic device 1000 to achieve cooling and additional positioning function. For example, the electronic device 1000 may be a server device that requires a lot of circuit boards and hardware to achieve the intended computational tasks. However, the forms of the electronic devices 1000 according to the various embodiments of the present invention are not limited thereto. Specifically, the electronic device 1000 may include a housing 600 and an air baffle 10, wherein the housing 600 contains a first side plate 610 and a second side plate 620 disposed opposite each other, and the air baffle 10 is disposed within the housing 600 and at least partially laps over the housing 600. Similar to the embodiments shown in FIGS. 1 to 8, referring to the enlarged view of the region A2 shown in FIG. 9, the air baffle 10 may include a base 100, a holding portion H disposed on the base 100, a first positioning portion 300 and a second positioning portion 400 disposed on one side of the holding portion H and respectively close to the first vertical plate 210 and second vertical plate 220, and a module body 500 disposed between the first positioning portion 300 and the second positioning portion 400. As mentioned above, the support module KM including the first positioning portion 300, the second positioning portion 400, and the module body 500 may be configured based on the same or similar forms as the embodiments described with reference to FIGS. 1 to 8. Therefore, the module body 500 can move within the air baffle 10 along the predetermined direction such as the first direction D1, further achieving positioning by fastening into the predetermined grooves.

For example, as shown in FIG. 9, the electronic device 1000 may further include an expansion card slot CL used to store the predetermined component M (for example, an expansion card PI). Specifically, the electronic device 1000 may have the expansion card slot CL used to be electrically connected to the expansion card PI, and the port end Pr of the expansion card PI may be inserted into the expansion card slot CL. When the expansion card PI is positioned within the electronic device 1000, the expansion card PI is in the expansion card slot CL, and a portion of the expansion card PI is supported by the holding portion H of the air baffle 10. The end Pe being clamped by the module body 500 and the port end Pr are on different sides of the expansion card PI. As mentioned above, the configuration according to this embodiment can reduce or prevent the situation of the end Pe of the expansion card PI being suspended, thereby enhancing the fixation and protection of the expansion card PI, and reducing or preventing damage or misalignment of the expansion card PI due to impact or vibrations.

Furthermore, referring to FIG. 9, according to this embodiment, the first side wall E1 of the air baffle 10 laps over the first side plate 610 of the housing 600, and the second side wall E2 of the air baffle 10 laps over the second side plate 620 of the housing 600. Therefore, when the module body 500 of the air baffle 10 is used to further secure the predetermined component M (for example, the expansion card PI), the weight of the expansion card PI can be further transferred to the first side plate 610 and the second side plate 620 of the housing 600 through the first supporting wing W1 and the second supporting wing W2, thereby improving the support to and stability of the predetermined component M when using the air baffle 10 for fixation, wherein the air baffle 10 has relatively low weight because of the flow-guiding via holes GH thereon. In addition, according to some embodiments, the first side plate 610 and the second side plate 620 may respectively have at least one first holding groove TH1 and at least one second holding groove TH2, and the first side wall E1 and the second side wall E2 of the air baffle 10 may respectively have at least one bump BM protruding away from the first side wall E1 and at least one bump BM protruding away from the second side wall E2. The bumps BM may respectively correspond to and fit into the first holding groove TH1 and the second holding groove TH2, thereby securing the air baffle 10 in housing 600, and reducing or preventing wobbling or misalignment of the predetermined component M supported by the holding portion H of the air baffle 10.

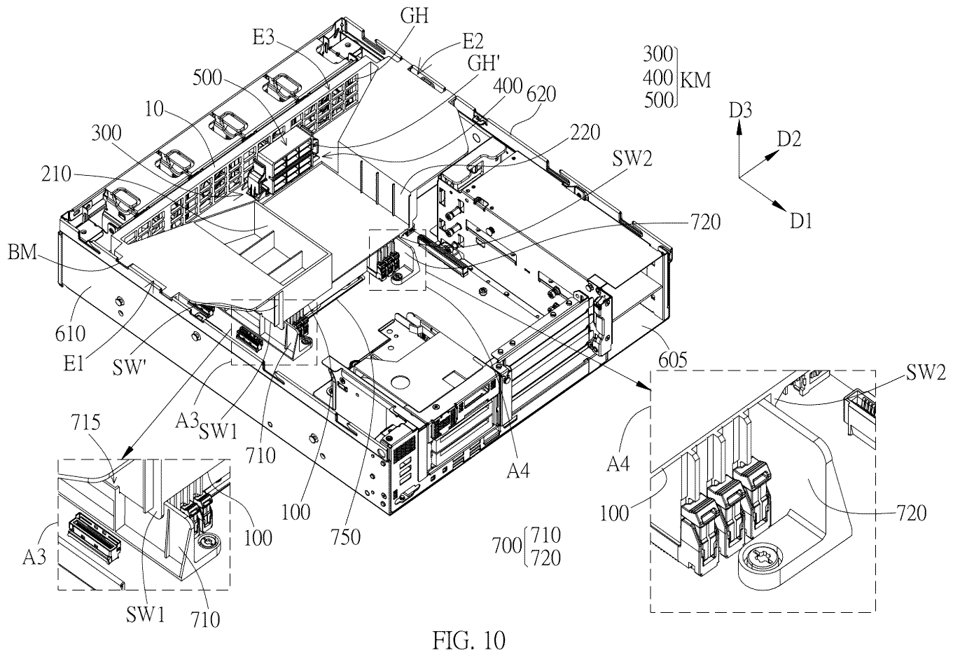

Furthermore, referring to FIGS. 9 to 11, the electronic device 1000 according to this embodiment may further include: a holder 700 disposed on a bottom plate 605 of the housing 600 and connected to the air baffle 10 (for example, a memory module protecting board, known as a DIMM guard). The holder 700 can support the base 100 of the air baffle 10. Specifically, referring to FIG. 10, where some components are omitted to clearly illustrate the configuration relationship between the holder 700 and the base 100 of the air baffle 10, the holder 700 includes a first blocking plate 710 and a second blocking plate 720 disposed on the bottom plate 605 of the housing 600 according to this embodiment. The first blocking plate 710 and the second blocking plate 710 are respectively disposed close to the first side plate 610 and the second side plate 620, and the base 100 of the air baffle 10 may abut the top faces of the first blocking plate 710 and the second blocking plate 720, allowing the air baffle 10 to be supported by the first blocking plate 710 and the second blocking plate 720. In addition, components for protecting the intended memory module 750 or other components may be positioned between the first blocking plate 710 and the second blocking plate 720, but not limited thereto. In addition, referring to the enlarged view of the region A3 and the region A4, the air baffle 10 may further have a first supporting wall SW1 and a second supporting wall SW2 extending from the base 100 to the holder 700, away from the support module KM, wherein the first supporting wall SW1 may lean against or abut a side of the first blocking plate 710 facing away from the second blocking plate 720, and the second supporting wall SW2 may lean against or abut a side of the second blocking plate 720 facing away from the first blocking plate 710. Therefore, when the air baffle 10 is clamping or protecting the predetermined component M as aforementioned, the weight of the air baffle 10 can be further transferred to the holder 700 within the housing 600 along the vertical direction such as the third direction D3, thereby improving the support to and stability of the predetermined component M when using the air baffle 10 for fixation, wherein the air baffle 10 has relatively low weight because of the flow-guiding via holes GH thereon.

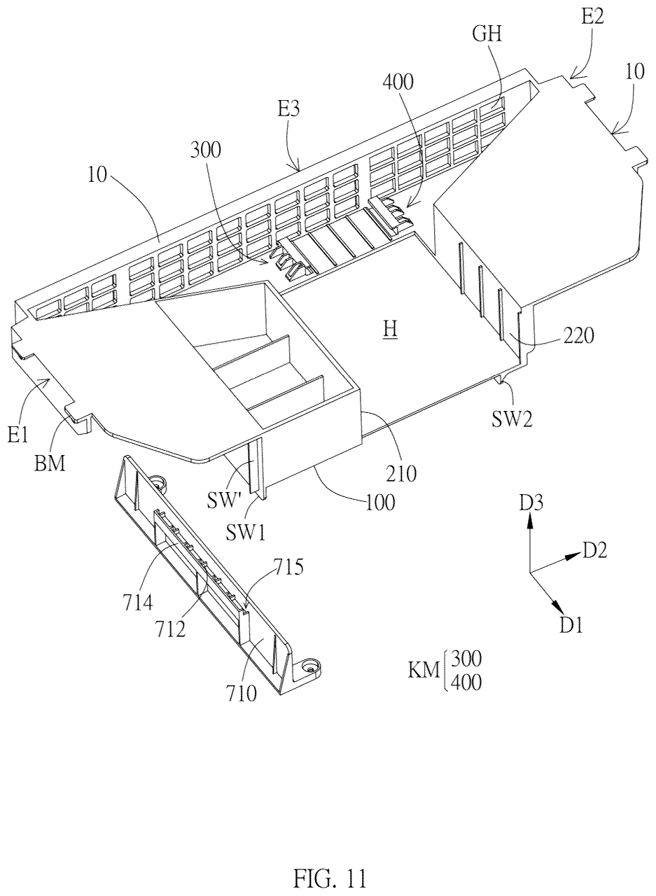

According to some embodiments, as shown in FIGS. 10 and 11, in order to strengthen the structure and effectively transfer weight or stress, the first supporting wall SW1 and the second supporting wall SW2 may also have some reinforced rib structure SW′, but approaches for reinforcement are not limited thereto.

Furthermore, referring to FIGS. 10 and 11, according to this embodiment, the first blocking plate 710 may have a first slot 715 disposed on the surface of the first blocking plate 710 facing away from the second blocking plate 720 and opening toward the base 100, wherein the first slot 715 can provide support for the first supporting wall SW1 in different directions. For example, one or more ribs 712 of the first slot 715 can provide support and position-limiting function for the first supporting wall SW1 in the vertical direction such as the third direction D3, and the outer side wall 714 of the first slot 715 and a surface of the first blocking plate 710 may provide support and position-limiting function for the first supporting wall SW1 in the horizontal direction such as the second direction D2. Similarly, the second blocking plate 720 may have a second slot (not shown in the figures due to viewing angle constraints) disposed on a surface of the second blocking plate 720 and opening toward the base 100, and the second slot can have the same or similar function and configuration of the first slot 715; hence, it will not be elaborated further here. As mentioned above, the first supporting wall SW1 and the second supporting wall SW2 can be inserted into the first slot 715 and the second slot to further enhance the positioning.

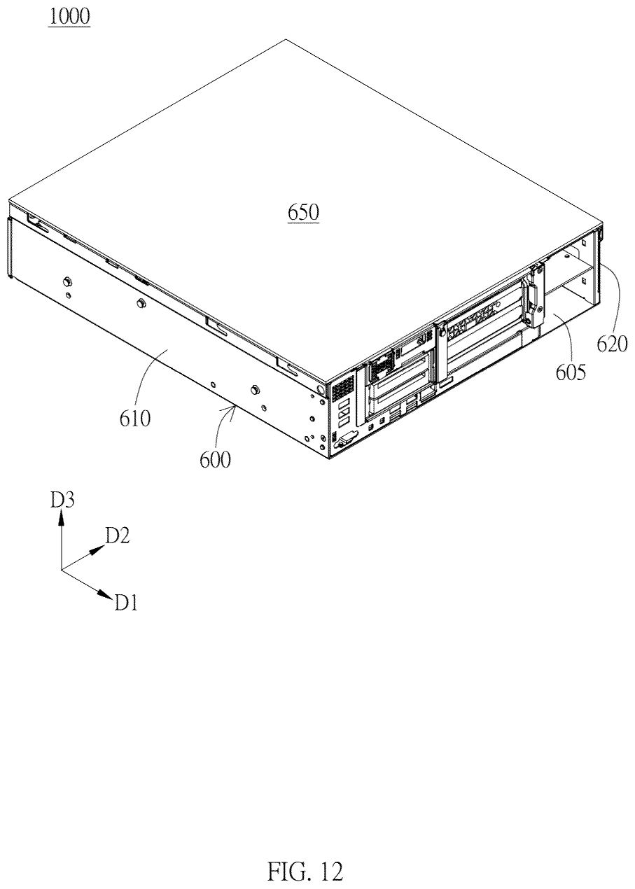

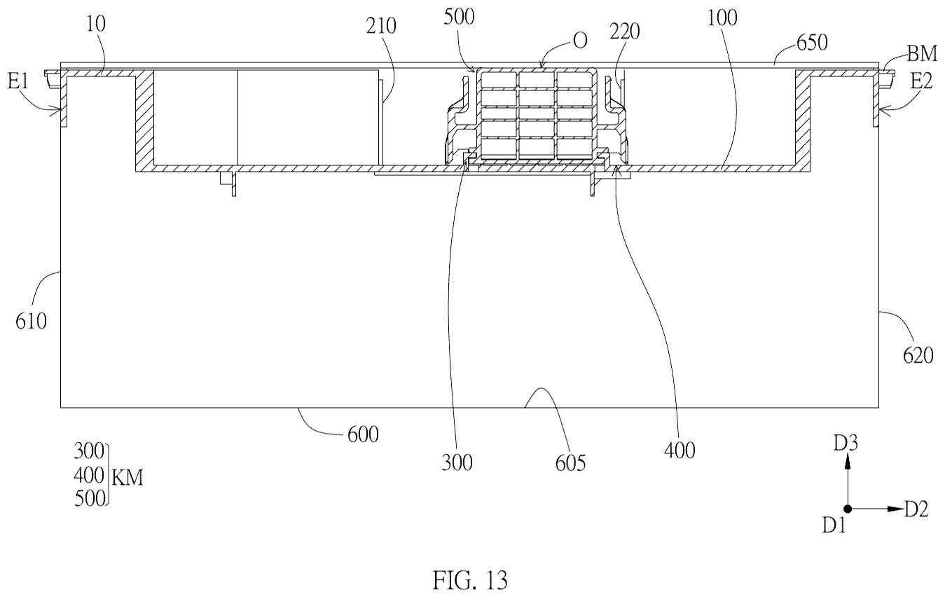

Next, referring to FIGS. 12 and 13, the corresponding configuration relationship of the support module KM and the top cover 650 according to this embodiment will be further illustrated.

According to another embodiment of the present invention, the electronic device 1000 may further include a top cover 650 matching with the housing 600. Referring to the configuration of the air baffle 10, the housing 600, and the top cover 650 as shown in FIG. 13 (other components are omitted for clarity), when the top cover 650 covers the housing 600, the top flange O of the module body 500, facing away from the base 100, may directly abut the top cover 650; or, a gap may be designed between the top flange O and the top cover 650 to allow the top flange O to directly abut the top cover 650 when shaking occurs, thereby limiting the displacement possibly caused by shaking. Therefore, in the vertical direction such as the third direction D3, the air baffle 10 can not only distribute the load and enhance support to the housing 600 and the holder 700 as mentioned above, but also enhance the positioning and support by using the module body 500 to abut the top cover 650. For example, when impact or shaking occurs, the stress on the predetermined component M clamped by the module body 500, along the vertical direction such as the third direction D3 and away from the base 100, may be transferred to the top cover 650, thereby reducing or preventing damage to the predetermined component M caused by the said stress. Moreover, the position of the predetermined component M may also be limited by the top cover 650 to reduce or prevent misalignment. In addition, based on this configuration, since the predetermined component M abuts the top cover 650 through the module body 500 but not directly abut the top cover 650, according to this embodiment, predetermined component M can also be reduced or prevented from directly colliding with or rubbing against the top cover 650, thereby preventing unintended damage.

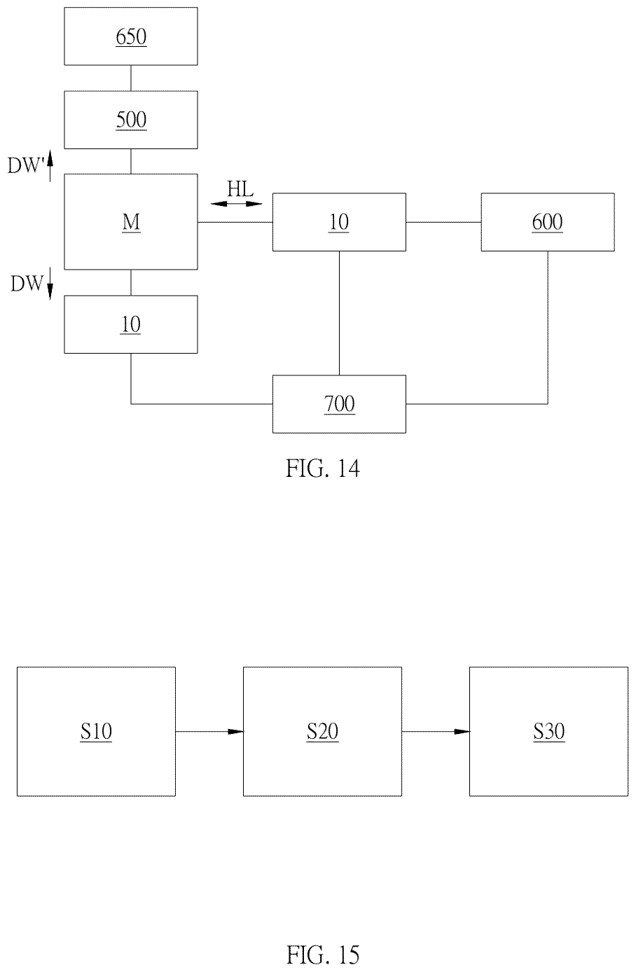

Further referring to FIG. 14, the schematic view of the paths of stress and weight transfer and dispersion as mentioned above is shown in an integrated manner. The weight of the predetermined component M such as an expansion card itself and the potential stress thereon may be transferred to a portion of the air baffle 10 in the horizontal direction HL and the gravitational direction DW, and may be further transferred to the housing 600 in the horizontal direction HL or be transferred to the holder 700 along the gravitational direction DW. In addition, the weight of the predetermined component M such as an expansion card itself and the potential stress thereon may be transferred to module body 500 in a direction DW′ opposite to the gravitational direction DW, then continue to be transferred to the top cover 650 in the direction DW′. As shown in FIG. 14, based on this configuration, the weight of the predetermined component M such as an expansion card itself and the potential stress thereon can be effectively dispersed to the respective components or structures, thereby securely positioning the predetermined component M and reducing or preventing damage to or misalignment of the predetermined component M.

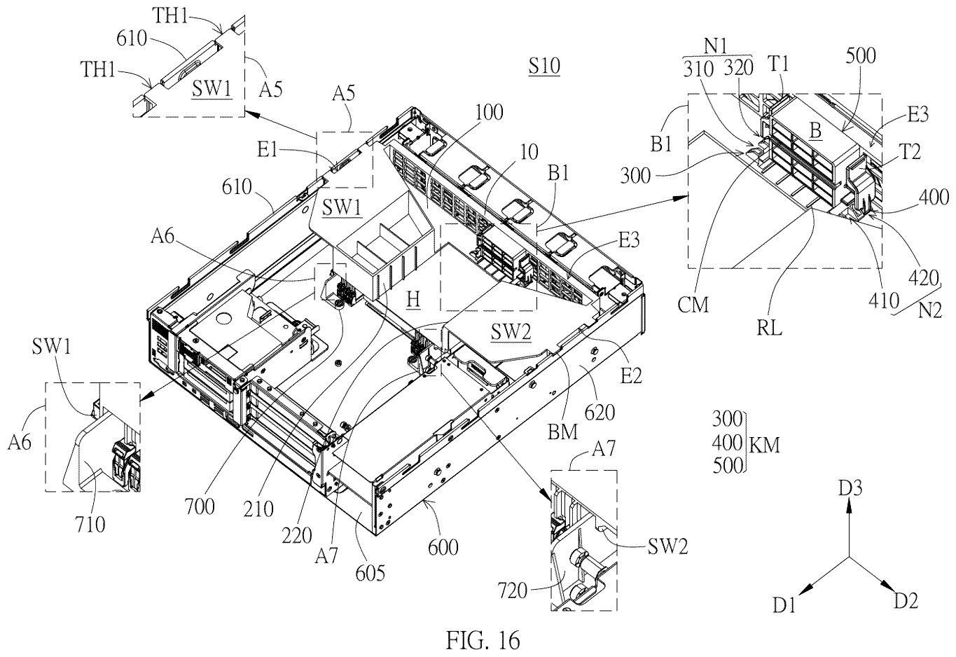

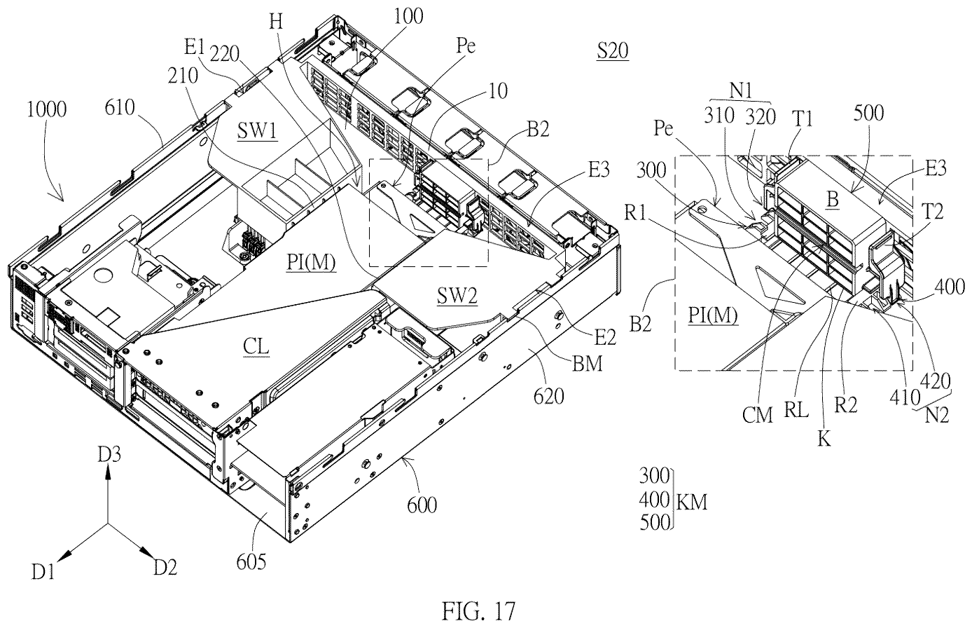

Next, referring to FIGS. 16 to 18, along with FIG. 15, the process of assembling an electronic device according to an embodiment of the present disclosure will be described in detail, especially the assembling process of the air baffle and the predetermined component secured by the air baffle.

Specifically, referring to FIGS. 15 and 16, according to step S10 of the assembling method in this embodiment, the air baffle 10 similar to or the same as the air baffle in the various embodiments described above may be first positioned and secured onto the housing 600 with the holder 700. As mentioned above, referring to the enlarged view of the region A5, A6, and A7, the first side wall E1 and the second side wall E2 of the air baffle 10 respectively lap over the first side plate 610 and the second side plate 620 of the housing 600. The base 100 of the air baffle 10 is supported by the holder 700. Referring to the enlarged view of the region B1, the module body 500 may be positioned away from the holding portion H (for example, in the first groove 320 and the second groove 420 away from the holding portion H).

Next, referring to FIGS. 15 and 17, after positioning and securing the air baffle 10, the expansion card slot CL and the expansion card PI as the predetermined component M may be further positioned and secured in step S20. The expansion card PI may be first positioned and secured into the expansion card slot CL, then locked into the housing 600 together with the expansion card slot CL. Furthermore, the end Pe of the expansion card PI which is not housed in the expansion card slot CL may be placed in the holding portion H of the air baffle 10 and be supported by the air baffle 10. In the present step S20, referring to the enlarged view of the region B2, the module body 500 is not in contact with the expansion card PI, and is separated from the end Pe of the expansion card PI by a distance. Therefore, according to this embodiment, the expansion card slot CL and the expansion card PI can be installed into the housing 600 from the outside without hindrance, thus making assembly more convenient.

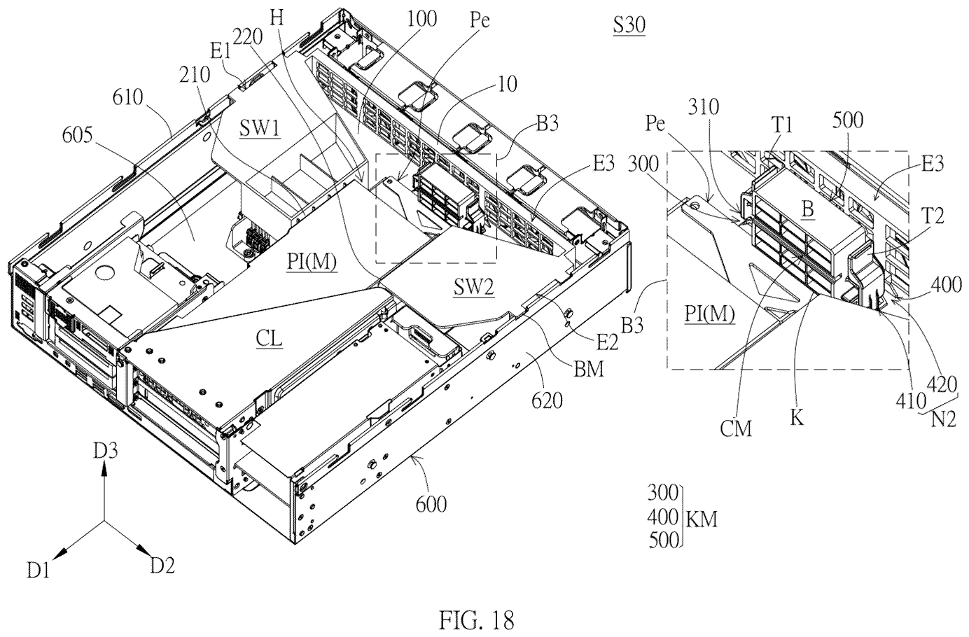

Referring to FIGS. 15, 17 and 18, after installing the expansion card PI and inserting the expansion card PI into the holding portion H, as mentioned above, the first insert end n1 of the first arm T1 and the second insert end n2 of the second arm T2 can be respectively removed from the first groove 320 and the second groove 420, which are away from the holding portion H, thus the module body 500 can move toward the holding portion H using the first slide rail G1 and the second slide rail G2 respectively along the first guide rail R1 and the second guide rail R2. Lastly, for step S30 shown in FIG. 18, referring to the enlarged view of the region B3, the end Pe of the expansion card PI can be clamped by the clamping slot CM or the bottom edge K of the module body 500, and the first insert end n1 of the first arm T1 and the second insert end n2 of the second arm T2 can be respectively moved into the first groove 310 and the second groove 410, which are close to the holding portion H to achieve positioning.

As mentioned above, by using the module body 500 clamped to the end Pe of the expansion card PI, the positioning and protection of the expansion card PI can be enhanced beyond the intended installing process. According to this embodiment, the user can easily position the expansion card PI by sliding the module body 500 as well as remove the expansion card PI by sliding the module body 500 clamped to the end Pe of the expansion card PI in the reversed direction. In addition, since the above structure integrates air baffle 10 and expansion card PI, the space originally occupied by the separate assembly of these components can be reduced, which further saves space and is beneficial for cable routing and management. For example, cable routing and management can be done in the space between the first supporting wing SW1 and the second supporting wing SW2 on both sides of the air baffle 10 and the bottom plate 605 of the housing 600, thus reducing or preventing impact on the computational components or fragile components positioned therebetween. However, the achievable paths and forms are not limited to this example. Therefore, according to this embodiment, a structure module that integrates flow-guided cooling, positioning and protection, and cable routing and management functions can be implemented in the assembled electronic device 1000, thereby enhancing the space utilization efficiency and the reliability of securing and positioning.

In summary, based on the air baffle and the electronic device including the air baffle provided in various embodiments of the present invention, the air baffle for cooling can be utilized to conveniently secure and protect the predetermined component, thereby improving space allocation and further enhancing the robustness and protection of the predetermined component. In addition, based on the air baffle and the electronic device including the air baffle provided in various embodiments of the present invention, fastening and unfastening can be achieved by simple operations, facilitating securing and positioning. Therefore, based on the air baffle and the electronic device including the air baffle provided in various embodiments of the present invention, overall space utilization and support can be enhanced while achieving the intended functionality and cooling performance of each component.

The above context merely illustrates some preferred embodiments of the present disclosure. It should be noticed that various changes and modifications can be made to the present disclosure without departing from the spirit and principles of the present disclosure. It should be understood by a person having ordinary skill in the art that the present disclosure is defined by the scope of the appended patent claims, and that various possible substitutions, combinations, modifications, and adaptations, which align with the intent of the present disclosure, fall within the scope of the present disclosure as defined by the appended patent claims.

What is claimed is:

1. An air baffle, comprising:
a base;
a first side wall, a second side wall and a third side wall, wherein the first side wall and the second side wall are respectively connected to the third side wall, and the third side wall is connected to the base;
a first vertical plate and a second vertical plate, disposed on the base and defining a holding portion collectively with the base, wherein the first vertical plate and the second vertical plate are respectively close to the first side wall and the second side wall; and
a support module, disposed between the third side wall and the holding portion.

2. The air baffle of claim 1, wherein the support module comprises a first positioning portion a second positioning portion and a module body, the first positioning portion and the second positioning portion are disposed on the base and respectively close to the first vertical plate and second vertical plate; the first positioning portion has a first guide rail extending toward the second positioning portion, the second positioning portion has a second guide rail extending toward the first positioning portion, the module body has a first slide rail and a second slide rail, the first slide rail and the second slide rail of the module body respectively fit with the first guide rail of the first positioning portion and the second guide rail of the second positioning portion, the module body is slidably positioned on the base and is moved toward or away from the holding portion.

3. The air baffle of claim 2, wherein the first positioning portion of the support module has at least one first groove, the second positioning portion has at least one second groove, two sides of the module body respectively have a first arm and a second arm, the first arm and the second arm are respectively extended to one of the first groove(s) and one of the second groove(s) to position the module body.

4. The air baffle of claim 3, wherein the first arm and the second arm have a first insert end and a second insert end respectively, and the first insert end is extended in the one of the first groove(s) and the second insert end is extended in the one of the second groove(s) to position the module body.

5. The air baffle of claim 4, wherein the first insert end and the second insert end each has a reinforcing end piece.

6. The air baffle of claim 1, wherein the third side wall has a plurality of flow-guiding via holes, a module body of the support module has a plurality of air channels, the plurality of air channels of the module body are connected to the plurality of flow-guiding via holes of the third side wall.

7. The air baffle of claim 1, wherein the air baffle comprises a first supporting wing and a second supporting wing, the first supporting wing is connected to the first side wall and the first vertical plate, the second supporting wing is connected to the second side wall and the second vertical plate.

8. The air baffle of claim 1, wherein the first vertical plate and the second vertical plate each has a rib part.

9. The air baffle of claim 1, wherein the support module comprises a module body, and the module body is formed with a clamping slot.

10. An electronic device, comprising:
a housing containing a first side plate and a second side plate disposed opposite each other; and
an air baffle disposed within the housing, and the air baffle comprises:
a base;
a first side wall, a second side wall and a third side wall, wherein the first side wall and the second side wall are respectively connected to the third side wall, and the third side wall is connected to the base;
a first vertical plate and a second vertical plate, disposed on the base and defining a holding portion collectively with the base, wherein the first vertical plate and the second vertical plate are respectively close to the first side wall and the second side wall; and
a support module, disposed between the third side wall and the holding portion;
wherein the first side wall and the second side wall of the air baffle respectively lap over the first side plate and the second side plate of the housing.

11. The electronic device of claim 10, wherein the first side wall of the air baffle has at least one bump protruding away from the first side wall, the second side wall of the air baffle has at least one bump extending and protruding from the second side wall, the first side plate of the housing has a first holding groove fitting with the at least one bump of the first side wall, and the second side plate of the housing has a second holding groove fitting with the at least one bump of the second side wall.

12. The electronic device of claim 10, further comprising a holder, disposed on a bottom plate of the housing and connected to the air baffle.

13. The electronic device of claim 12, wherein the holder comprises a first blocking plate and a second blocking plate respectively close to the first side plate and the second side plate, the air baffle has a first supporting wall and a second supporting wall extending from the base toward the holder, the first supporting wall and the second supporting wall respectively abut a surface of the first blocking plate and a surface of the second blocking plate.

14. The electronic device of claim 13, wherein the first blocking plate has a first slot disposed on a surface of the first blocking plate and opening toward the base, the second blocking plate has a second slot disposed on a surface of the second blocking plate and opening toward the base, the first supporting wall and the second supporting wall is respectively inserted into the first slot and the second slot.

15. The electronic device of claim 10, wherein the holding portion is used to hold an expansion card, and a module body of the support module is used to clamp an end of the expansion card between a bottom edge of the module body and the base.

16. The electronic device of claim 15, wherein the module body of the support module has a clamping slot, the end of the expansion card is clamped by the clamping slot.

17. The electronic device of claim 15, wherein the first vertical plate and the second vertical plate each has a rib part, two sides of the expansion card are abutted by the rib part.

18. The electronic device of claim 10, wherein the support module comprises a first positioning portion, a second positioning portion and a module body, the first positioning portion and the second positioning portion are disposed on the base and respectively close to the first vertical plate and second vertical plate; the first positioning portion has a first guide rail extending toward the second positioning portion, the second positioning portion has a second guide rail extending toward the first positioning portion, the module body has a first slide rail and a second slide rail, the first slide rail and the second slide rail of the module body respectively fit with the first guide rail of the first positioning portion and the second guide rail of the second positioning portion, allowing the module body to be slidably positioned on the base and moved toward or away from the holding portion.

19. The electronic device of claim 18, wherein the first positioning portion of the support module has at least one first groove, the second positioning portion has at least one second groove, two sides of the module body respectively have a first arm and a second arm, the first arm and the second arm are respectively extended to one of the first groove(s) and one of the second groove(s) to position the module body.

20. The electronic device of claim 10, wherein the electronic device comprises a top cover, the support module comprises a module body, and the top flange of the module body abut the top cover.
